(19) United States
(12) Patent Application Publication
(10) Pub. No.: US 2012/0153481 A1
(43) Pub. Date: Jun. 21, 2012

(54) SEMICONDUCTOR DEVICE AND METHOD FOR MANUFACTURING THE SAME

(75) Inventor: Sung Hwan AHN, Suwon (KR)

(73) Assignee: Hynix Semiconductor Inc., Icheon (KR)

(21) Appl. No.: 13/327,590

(22) Filed: Dec. 15, 2011

(30) Foreign Application Priority Data
Dec. 15, 2010 (KR) 10-2010-0128573

(51) Int. Cl. H01L 29/43; H01L 23/48; H01L 21/768

(52) U.S. Cl. 257/751; 438/653; 257/774; 257/E21.577; 257/E23.021; 257/E29.139

(57) ABSTRACT

A semiconductor device and a method for manufacturing the same are disclosed, which can prevent a short-circuit between a bit line contact plug and a storage node contact plug, resulting in improved semiconductor device characteristics. A method for manufacturing a semiconductor device includes: forming a bit line contact hole from which an active region is protruded, by etching a semiconductor substrate; forming a conductive material over the semiconductor substrate including the bit line contact hole; etching the conductive material to form a bit line contact plug and a bit line, each of which has a smaller width than the bit line contact hole; and forming a spacer insulation film over the entire surface of the semiconductor substrate including the bit line contact hole, the bit line contact plug, and the bit line.

### CROSS-REFERENCE TO RELATED APPLICATION

The priority of Korean patent application No. 10-2010-0128573 filed on 15 Dec. 2010, the disclosure of which is hereby incorporated in its entirety by reference, is claimed.

### BACKGROUND OF THE INVENTION

Embodiments of the present invention relate to a semiconductor device and a method for manufacturing the same, and more particularly to a semiconductor device including an inner bit line and a method for manufacturing the same.

In recent times, technologies of 40 nm or less have been applied to semiconductor devices so that a Global Bit Line (GBL) process has been proposed. However, if misalignment between a bit line contact and a bit line occurs, the GBL process unavoidably generates a poor self-aligned contact (SAC) between a bit line contact and a storage node contact. When a thick bit line spacer is formed to solve the above-mentioned problem, a Not-Open phenomenon of a storage node contact occurs. In addition, if the bit line contact spacer is formed thick, resistance of the bit line contact increases. In order to prevent resistance of the bit line contact from increasing, an inner GBL process has been proposed. However, in an inner GBL process, a bit line contact plug is coupled to an active region between buried gates, and the bit line is coupled to an upper part of the bit line contact plug. In addition, the storage node contact plug is located at both sides of the bit line and is coupled to the active region. However, since the bit line contact plug is formed close to the storage node contact plug, the bit line contact plug is likely to be coupled to the storage node contact plug located at both sides of the bit line, resulting in a short-circuit between the bit line contact plug and the storage node contact plug.

In order to prevent a short-circuit between the bit line contact plug and the storage node contact plug, the bit line may be formed to have a large width or a spacer may be formed thickly over sidewalls of the bit line. However, in such case, a coupling region between the active region and the storage node contact plug is reduced in size, resulting in increased resistance.

### BRIEF SUMMARY OF THE INVENTION

Various embodiments of the present invention are directed to providing a semiconductor device and a method for manufacturing the same that substantially obviate one or more problems due to limitations and disadvantages of the related art.

An embodiment of the present invention relates to a semiconductor device and a method for manufacturing the same, which can improve device characteristics by improving a process of forming a bit line contact plug.

In accordance with an aspect of the present invention, a method for manufacturing a semiconductor device includes: forming a bit line contact hole from which an active region is protruded, by etching a semiconductor substrate; forming a conductive material over the semiconductor substrate including the bit line contact hole; etching the conductive material to form a bit line contact plug and a bit line, each of which has a smaller width than the bit line contact hole; and forming a spacer insulation film over the entire surface of the semiconductor substrate including the bit line contact hole, the bit line contact plug, and the bit line.

In the forming of the bit line contact hole, width of the bit line contact hole may be larger than a width of the active region.

In the forming of the bit line contact hole, the active region may be protruded from the center part of the bit line contact hole. The forming of the bit line and the bit line contact plug may include: forming a polysilicon layer, a barrier metal layer, a bit line conductive layer, and a hard mask layer over the bit line contact hole; forming a photoresist pattern defining the bit line over the hard mask layer; and etching the hard mask layer, the bit line conductive layer, the barrier metal layer, and the polysilicon layer using the photoresist pattern defining the bit line as an etch mask.

The barrier metal layer may be formed of any of a titanium film, a titanium nitride film, and a combination thereof. The bit line conductive layer may be formed of a material including tungsten (W). The bit line hard mask layer may be formed of a material including a nitride film.

In the forming of the spacer insulation film, the spacer insulation film may be formed to fill the bit line contact hole formed over sidewalls of the bit line contact plug. In the forming of the spacer insulation film, the spacer insulation film may be formed of a material including a nitride film. The method may further include, after forming the spacer insulation film, forming a storage node contact plug adjacent to the bit line.

The forming of the storage node contact plug may include: forming an interlayer insulation film over the spacer insulation film; forming a mask pattern defining a storage node contact hole over the interlayer insulation film; etching the interlayer insulation film using the mask pattern and the spacer insulation film formed over sidewalls of the bit line as an etch mask; forming a storage node contact hole exposing the semiconductor substrate by etching the spacer insulation film formed over the semiconductor substrate; and forming a conductive layer to fill the storage node contact hole.

The forming of the storage node contact hole is performed using a mixture gas having carbon(C)/fluorine(F) in which a carbon(C) ratio is 40% or greater with respect to fluorine(F). The forming of the storage node contact hole may be performed using gas including any of C₄F₆, C₅F₈, C₄F₈, and a combination thereof.

In accordance with another aspect of the present invention, a semiconductor device includes: a bit line contact hole including a protruded active region; a bit line contact plug and a bit line coupled to an upper part of the active region; and a spacer insulation film formed over the entire surface including the bit line contact plug and the bit line.

Width of the bit line contact hole may be larger than a width in the active region. Width of the bit line contact plug may be smaller than a width of the bit line contact hole.

The bit line contact plug may include polysilicon. The bit line includes a laminated structure of a barrier metal layer, a bit line conductive layer, and a bit line hard mask. The spacer insulation film may include a nitride film.

The spacer insulation film may be buried between the bit line contact plug and the bit line contact hole. The semiconductor device may further include a storage node contact plug formed adjacent to the bit line.

It is to be understood that both the foregoing general description and the following detailed description of the present invention are exemplary and explanatory and are intended to provide further explanation of the invention as claimed.

### BRIEF DESCRIPTION OF THE DRAWINGS

FIGS. 1 to 7 are cross-sectional views illustrating a semiconductor device and a method for manufacturing the same according to an embodiment of the present invention.

### DESCRIPTION OF EMBODIMENTS

Reference will now be made in detail to embodiments of the present invention, examples of which are illustrated in the accompanying drawings. Wherever possible, the same reference numbers will be used throughout the drawings to refer to the same or like parts. A semiconductor device and a method for manufacturing the same according to embodiments of the present invention will hereinafter be described with reference to the accompanying drawings.

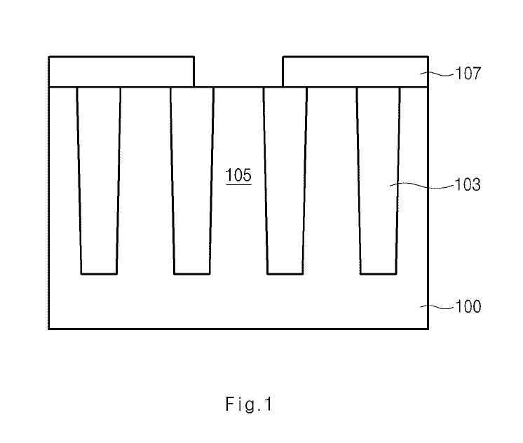

FIGS. 1 to 7 are cross-sectional views illustrating a semiconductor device and a method for manufacturing the same according to an embodiment of the present invention.

Referring to FIG. 1, a trench for a device isolation film defining an active region 105 is formed by etching a semiconductor substrate 100. A liner oxide film (not shown) and a liner nitride film (not shown) are formed at an inner wall of the trench. In an embodiment, the liner oxide film (not shown) may increase a deposition rate of a liner nitride film, which is formed in a subsequent process, and the liner nitride film (not shown) may absorb or buffer stress caused by a difference in the thermal expansion coefficient between the liner nitride film and an insulation film for device isolation.

Thereafter, an insulation film for device isolation is formed over the semiconductor substrate 100 including the trench, and a planarization etching process is performed on the resultant insulation film, so that a device isolation film 103 is formed. In an embodiment, the device isolation film 103 may include any of Spin On Dielectric (SOD), High Density Plasma (HDP), and a combination thereof. Although not shown in FIG. 1, after the formation of the device isolation film 103, the device isolation film 103 and the active region 105 may be etched to form a recess, and a buried gate may be buried in the recess. However, a process for forming a buried gate and a detailed description of the buried gate will be omitted for the convenience of description and better understanding of the present invention.

Thereafter, a mask pattern 107 exposing a region reserved for a bit line contact hole is formed over the semiconductor substrate 100. Preferably, the mask pattern 107 may include an oxide film, a nitride film, and the like.

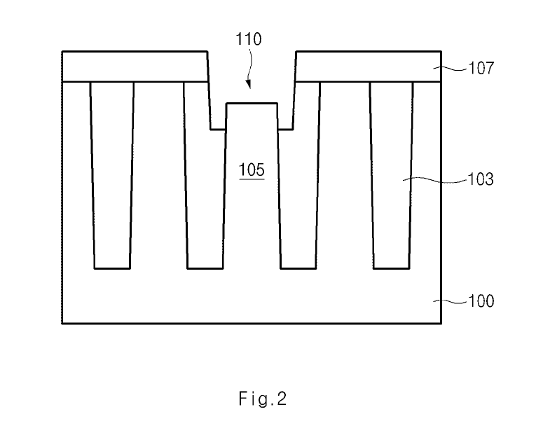

Referring to FIG. 2, the semiconductor substrate 100 is etched using the mask pattern 107 as an etch mask, so that a bit line contact hole 110 is formed. The bit line contact hole 110 is formed to expose the active region 105, and the bit line contact hole 110 may be formed to be larger than the active region 105 by 15 nm˜30 nm. At this time, provided that the active region 105 is etched to form the bit line contact hole 110, the device isolation film 103 is etched more deeply than the active region 105 due to a difference in an etch ratio between the active region 105 and the device isolation film 103. Consequently, the resultant bit line contact hole 110 is formed to have a protruded active region 105.

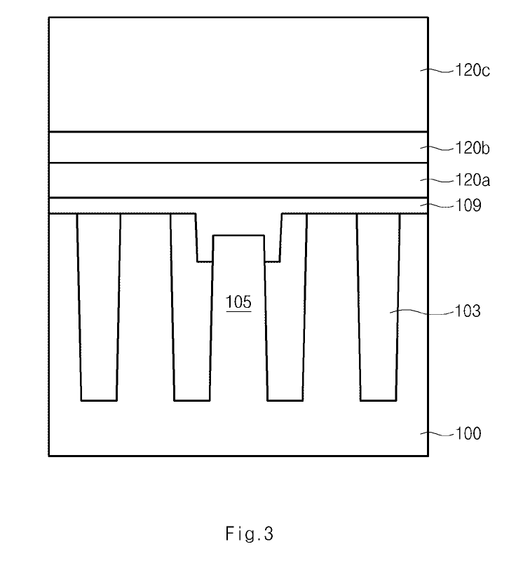

Referring to FIG. 3, after the mask pattern 107 has been removed, a polysilicon layer 109, a barrier metal layer 120a, a bit line conductive layer 120b, and a hard mask layer 120c are sequentially formed over the entire surface including the bit line contact hole 110. Preferably, an ion implantation process may be applied to the polysilicon layer 109. The bit line conductive layer 120b may include tungsten (W) having superior electrical conductivity. The barrier metal layer 120a may include any of a titanium film, a titanium nitride film, a tungsten nitride film, and a combination thereof. The hard mask layer 120c may include a nitride film.

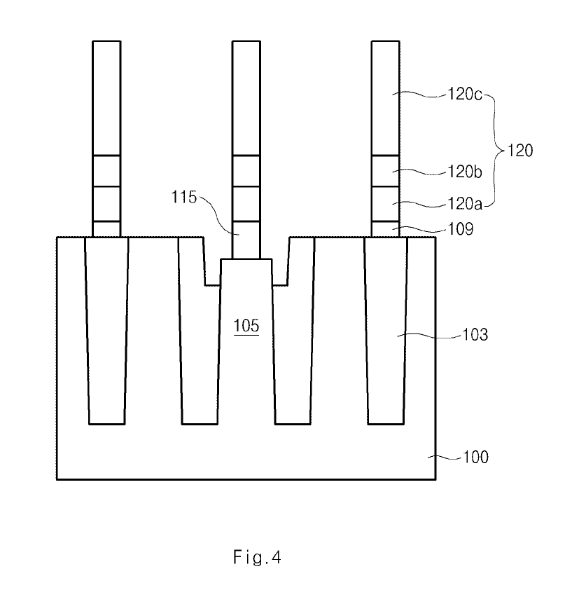

Referring to FIG. 4, a mask pattern (not shown) defining a bit line is formed over the hard mask layer 120c. The polysilicon layer 109, the barrier metal layer 120a, the bit line conductive layer 120b, and the hard mask layer 120c are etched using a mask pattern (not shown) as an etch mask. As a result, a bit line contact plug 115 formed of the polysilicon layer 109, and a bit line 120 formed of the barrier metal layer 120a, the bit line conductive layer 120b, and the hard mask layer 120c, are obtained. In accordance with an embodiment of the present invention, the bit line contact plug 115 and the bit line 120 are formed simultaneously, so that the bit line contact plug 115 has the same width as that of the bit line 120. Therefore, the bit line contact plug 115 has a smaller width than that of the bit line contact hole 110.

As described above, since the bit line contact plug 115 has the same width as in the bit line 120, but a smaller width than the bit line contact hole 110, a short-circuit between the bit line contact plug 115 and the storage node contact plug, which will be formed in a subsequent process, can be prevented.

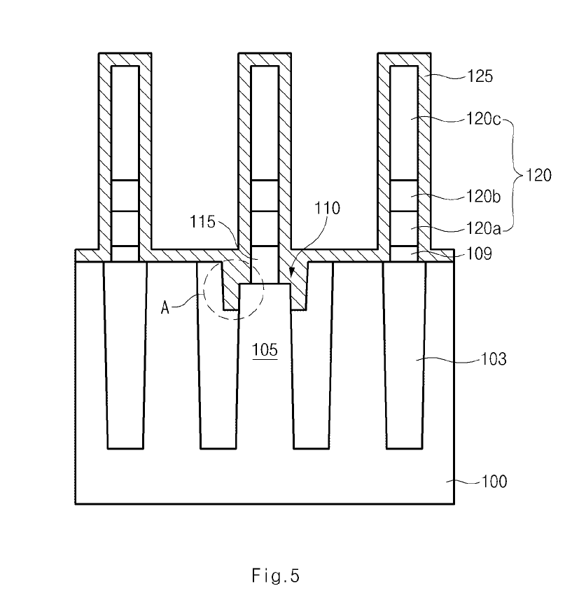

Referring to FIG. 5, a spacer insulation film 125 is formed over the semiconductor substrate 100 including the bit line 120 and the bit line contact plug 115. In an embodiment, the spacer insulation film 125 is deposited using a Chemical Vapor Deposition (CVD) method having superior gap filling characteristics, so that the spacer insulation film 125 can completely fill the bit line contact hole 110. See ‘A’ of FIG. 5. As a result, the spacer insulation film 125 may effectively prevent a bridge between the storage node contact plug and the bit line contact plug 110 from occurring in a subsequent process.

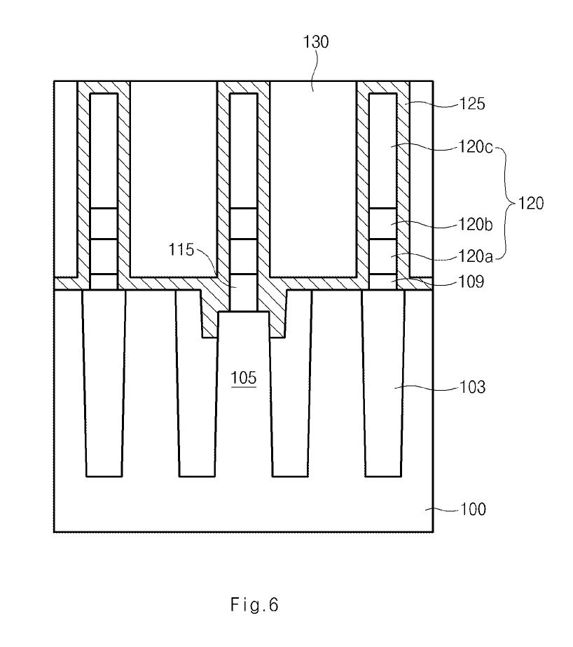

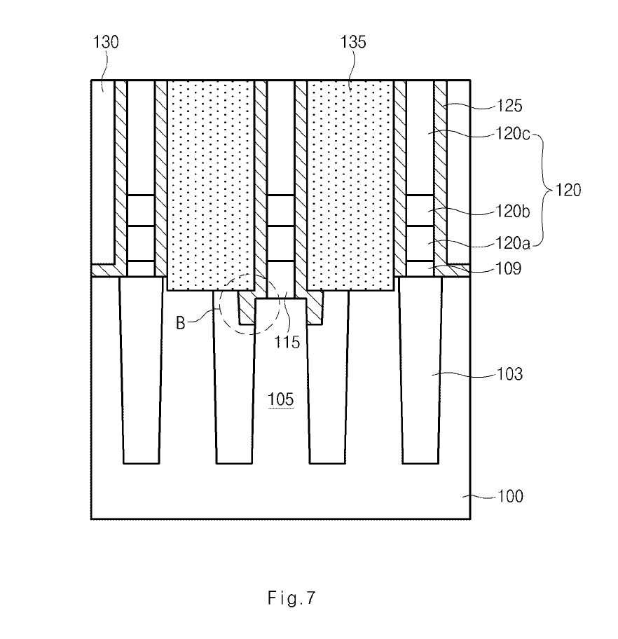

Referring to FIG. 6, an interlayer insulation film 130 is formed over the entirety of the semiconductor substrate 100, including the bit line 120 and the spacer insulation film 125. Referring to FIG. 7, a mask pattern (not shown) defining a storage node contact hole is formed over the interlayer insulation film 130. Subsequently, the interlayer insulation film 130 is etched using the mask pattern (not shown) and the spacer insulation film 125 formed at sidewalls of the bit line 120 as an etch mask. After that, the etching process is applied to form a storage node contact hole exposing the semiconductor substrate 100. In an embodiment, since the interlayer insulation film 130 is etched with an etch selection ratio different from that of the spacer insulation film 125, the spacer insulation film 125 formed at sidewalls of the bit line 120 is not damaged or lost, so that the bit line 120 and the bit line contact plug 115 are prevented from being lost or damaged. In an embodiment, the etch process for forming the storage node contact hole may be performed using a mixture gas of carbon(C) and fluorine(F) in which the carbon ratio is 40% or greater with respect to fluorine(F). For example, the above-mentioned etch process may be performed using gas including any of C₄F₆, C₅F₈, C₄F₈, and a combination thereof. Thereafter, a conductive layer is formed to fill the storage node contact hole, and is then planarized until the hard mask layer 120c is exposed, so that the storage node contact plug 135 is formed.

As can be seen from ‘B’ in FIG. 7, the spacer insulation film 125 formed at sidewalls of the bit line contact plug 115 is formed more deeply than the storage node contact plug 135, so that a short-circuit between the bit line contact plug 115 and the storage node contact plug 135 is prevented, thus preventing deterioration of semiconductor device characteristics.

A semiconductor device according an embodiment of the present invention will hereinafter be described with reference to FIG. 7. In an embodiment, the semiconductor device shown in FIG. 7 may be formed either in the same way or in a different way from the above-mentioned embodiments shown in FIGS. 1 to 6.

Referring to FIG. 7, the bit line contact hole 110 is located in the semiconductor substrate 100 including the active region 105 and the device isolation film 103. The active region 105 may be protruded from the center part of the bit line contact hole 110. The bit line contact plug 115 and the bit line 120 are formed over the protruded active region 105. Each of the bit line contact plug 115 and the bit line 120 may be formed to have a smaller width than the bit line contact hole 110. The bit line contact plug 115 includes a polysilicon layer, and the bit line 120 may include the barrier metal layer 120a, the bit line conductive layer 120b, and the bit line hard mask layer 120c.

The spacer insulation film 125 is formed over the entire surface, including the bit line contact plug 115 and the bit line 120. The spacer insulation film 125 completely fills the space between the bit line contact hole 110 and the bit line contact plug 115, and extends deeper than the storage node contact plug 135 neighboring the bit line 120.

As is apparent from the above description, in a semiconductor device and a method for forming the same according to embodiments of the present invention, the spacer insulation film 125 formed at sidewalls of the bit line contact plug 115 is formed more deeply than the storage node contact plug 135, as shown in ‘B’ in FIG. 7, so that a short-circuit between the bit line contact plug and the storage node contact plug is prevented, and therefore preventing semiconductor device characteristics from deteriorating.

The above embodiments of the present invention are illustrative and not limitative. Various alternatives and equivalents are possible. The invention is not limited by the embodiments described herein. Nor is the invention limited to any specific type of semiconductor device. Other additions, subtractions, or modifications are obvious in view of the present disclosure and are intended to fall within the scope of the appended claims.

What is claimed is:

1. A method for manufacturing a semiconductor device comprising:
forming a bit line contact hole, from which an active region is protruded, by etching a semiconductor substrate;
forming a conductive material over the semiconductor substrate including the bit line contact hole;
etching the conductive material to form a bit line contact plug and a bit line, each of which has a smaller width than the bit line contact hole; and
forming a spacer insulation film over the entire surface of the semiconductor substrate, including the bit line contact hole, the bit line contact plug, and the bit line.

2. The method according to claim 1, wherein, in the forming of the bit line contact hole, a width of the bit line contact hole is larger than a width of the active region.

3. The method according to claim 1, wherein the forming of the bit line and the bit line contact plug includes:
forming a polysilicon layer, a barrier metal layer, a bit line conductive layer, and a hard mask layer over the bit line contact hole;
forming a photoresist pattern defining the bit line over the hard mask layer; and
etching the hard mask layer, the bit line conductive layer, the barrier metal layer, and the polysilicon layer using the photoresist pattern defining the bit line as an etch mask.

4. The method according to claim 3, wherein the barrier metal layer is formed of any of a titanium film, a titanium nitride film, and a combination thereof.

5. The method according to claim 3, wherein the bit line conductive layer is formed of a material including tungsten (W).

6. The method according to claim 3, wherein the bit line hard mask layer is formed of a material including a nitride film.

7. The method according to claim 1, wherein the spacer insulation film is formed to fill the bit line contact hole formed at sidewalls of the bit line contact plug.

8. The method according to claim 1, wherein, the spacer insulation film is formed of a material including a nitride film.

9. The method according to claim 1, the method further comprising:
after forming the spacer insulation film, forming a storage node contact plug adjacent to the bit line.

10. The method according to claim 9, wherein the forming of the storage node contact plug includes:
forming an interlayer insulation film over the spacer insulation film;
forming a mask pattern defining a storage node contact hole over the interlayer insulation film;
etching the interlayer insulation film using the mask pattern and the spacer insulation film formed over sidewalls of the bit line as an etch mask;
forming a storage node contact hole exposing the semiconductor substrate by etching the spacer insulation film formed over the semiconductor substrate; and
forming a conductive layer to fill the storage node contact hole.

11. The method according to claim 10, wherein the forming of the storage node contact hole is performed using a mixture gas having carbon(C)/fluorine(F) in which a carbon(C) ratio is 40% or greater with respect to fluorine(F).

12. The method according to claim 11, wherein the forming of the storage node contact hole is performed using gas including any of C₄F₆, C₅F₈, C₄F₈, and a combination thereof.

13. A semiconductor device comprising:
a bit line contact hole including a protruded active region;
a bit line contact plug and a bit line coupled to an upper part of the active region; and
a spacer insulation film formed over the resultant including the bit line contact plug and the bit line.

14. The semiconductor device according to claim 13, wherein a width of the bit line contact hole is larger than a width of the active region.

15. The semiconductor device according to claim 13, wherein a width of the bit line contact plug is smaller than a width of the bit line contact hole.

16. The semiconductor device according to claim 13, wherein the bit line contact plug includes polysilicon.

17. The semiconductor device according to claim 13, wherein the bit line includes a laminated structure of a barrier metal layer, a bit line conductive layer, and a bit line hard mask.

18. The semiconductor device according to claim 13, wherein the spacer insulation film includes a nitride film.

19. The semiconductor device according to claim 13, wherein the spacer insulation film fills a space between the bit line contact plug and the bit line contact hole.

20. The semiconductor device according to claim 13, the device further comprising:
a storage node contact plug formed adjacent to the bit line.

21. A semiconductor device comprising:
a bit line contact plug (115) provided over an active region (105), wherein a width of the bit line contact plug is narrower than a width of the active region;
a storage node contact plug (135) provided adjacent to the bit line contact plug (115); and
a spacer insulation film (125) provided between the bit line contact plug (115) and the storage node contact plug (135),
wherein the spacer insulation film (125) vertically extends below a top surface of the active region (105) and horizontally extends below the storage node contact plug (135) so that the storage node contact plug (135) is insulated from the bit line contact plug (115) and the active region (105).
